(19) United States
(12) Patent Application Publication
(10) Pub. No.: US 2007/0126316 A1
(43) Pub. Date: Jun. 7, 2007

(54) ELECTRONIC DEVICE

(75) Inventors: Toshiya USUDA, Tokyo (JP); Hiroshi KINOSHITA, Tokyo (JP)

Correspondence Address: HARNESS, DICKEY & PIERCE, P.L.C., P.O. BOX 828, BLOOMFIELD HILLS, MI, 48303, US

(73) Assignee: EPSON TOYOCOM CORPORATION, Tokyo (JP)

(21) Appl. No.: 11/565,177

(22) Filed: Nov. 30, 2006

(30) Foreign Application Priority Data
Dec. 1, 2005 (JP) 2005-348050
Dec. 1, 2005 (JP) 2005-348051

(51) Int. Cl. H01L 41/00; H01L 23/02; H01L 23/48; H01L 23/12

(52) U.S. Cl. 310/348; 257/678; 257/704; 257/690

(57) ABSTRACT

An electronic device includes an electronic component, a package base having the electronic component therein and a conductive cover bonded to the package base, wherein a signal transmission line is provided to electrically connect the cover to the electronic component so as to use the cover as a terminal for inputting a signal to the electronic component from outside and wherein the signal transmission line is connected to a constant potential portion via an impedance element.

### BACKGROUND

1. Technical Field

The present invention relates to an electronic device, particularly to an electronic device in which a signal is input to an electronic component arranged therein after the formation of the electronic device.

2. Related Art

Some electronic devices have a package base with a recessed portion formed therein. The recessed portion has an electronic component mounted on a bottom surface thereof and a cover is bonded onto a top surface of the package base to seal the recessed portion. One example of such electronic devices is a piezoelectric oscillator. The piezoelectric oscillator has a package base in which a piezoelectric resonator element is disposed opposing the cover and an integrated circuit (IC) chip is provided as an electronic component to oscillate the piezoelectric resonator element to output a high-frequency oscillation signal. The piezoelectric resonator element is comprised of an electrode pattern disposed on each of upper and lower surfaces of a piezoelectric substrate. In addition, the cover is comprised of a metallic material such as kovar or the like. The piezoelectric oscillator is disclosed in an example of related art as below.

Meanwhile, in another piezoelectric oscillator having a package base including a piezoelectric resonator element arranged opposing a metallic cover as described above, the cover is electrically connected to an external terminal arranged on a back surface of the package base and having a ground potential. Such a piezoelectric oscillator is disclosed in another example of related art as below.

JP-A-8-307153 is a first example of related art.

JP-A-2000-77943 is a second example of related art.

In the case of the piezoelectric oscillator having a non-grounded metallic cover, when the package base includes a piezoelectric resonator element arranged opposing the metallic cover, stray capacitance occurs between the metallic cover and the electrode pattern of the piezoelectric resonator element. Then, after the shipment of the piezoelectric oscillator, if the cover is grounded or the like to supply a potential voltage, it changes a level of the stray capacitance occurring therebetween. Accordingly, there arises a problem of changing an oscillation frequency of the piezoelectric oscillator.

It will be described with a detailed example, as follows. On a module substrate incorporated in a mobile phone or the like are mounted various electronic devices including a piezoelectric oscillator. The substrate is disposed in a metallic container so that radio wave interferences such as radiation noise can be prevented. In this case, the container is connected to a ground potential so as to suppress noise radiated (radiation noise) from modules in the container. However, if the container has a dent made therein due to a shock or the like for some reason, there is a possibility that the container may contact with the cover of the piezoelectric oscillator. The contact therebetween changes the value of the stray capacitance between the electrode pattern of the piezoelectric resonator element and the cover, thereby changing an oscillation frequency of the piezoelectric oscillator.

Meanwhile, in the case of the piezoelectric oscillator whose cover is electrically connected to the grounded external terminal, the above problem does not arise. However, even in this piezoelectric oscillator, when a plurality of electrodes is arranged on an external side surface of the package base to input data to an IC chip, a malfunction is likely to occur upon data input. Specifically, when data is input to the piezoelectric oscillator, the piezoelectric oscillator is inserted into a socket and probes contact with the electrodes from an outside of the socket to input processing data via the probes. However, it is a difficult task to allow the probes to accurately contact with the electrodes arranged on the side surface. Therefore, a malfunction such as a data input failure occurs due to a poor contact.

Additionally, along with miniaturization of an electronic device such as a mobile phone, various electronic devices are mounted on a substrate at high density. Thus, when an electric signal is loaded due to an accidental contact of a piezoelectric oscillator with any of electronic devices adjacent thereto, it can cause alteration or deletion of data written into an IC chip in the piezoelectric oscillator.

### SUMMARY

An advantage of the present invention is to provide an electronic device capable of reliably inputting a signal to an electronic component arranged thereinside and preventing alteration and deletion of the signal written into the electronic component, where a cover has a constant potential in normal use.

An electronic device according to one aspect of the invention includes an electronic component, a package base having the electronic component therein and a conductive cover bonded to the package base, wherein a signal transmission line is provided to electrically connect the cover to the electronic component so as to use the cover as a terminal for inputting a signal to the electronic component from outside; and wherein the signal transmission line is connected to a constant potential portion via an impedance element.

In this manner, the cover can be connected to the constant potential portion via the impedance element. Thus, a signal input from the cover can be input to the electronic component via the signal transmission line. Meanwhile, in a normal use situation when no signal is input, the cover is connected to the constant potential portion via the impedance device. Accordingly, since the potential of the cover can be held constant, alteration and deletion of the signal written into the electronic component can be prevented. In addition, since the cover serves as the terminal to which a signal is input, a probe supplying a signal can easily be contacted with the cover, thereby ensuring signal input precisely.

Furthermore, the impedance element may be integrally formed with the electronic component. In this manner, since the impedance element is arranged inside the electronic component, it is unnecessary to dispose the impedance element as a discrete component in the package base. Thus, space saving in the package base can be achieved.

Furthermore, the package base may have the impedance element therein. When the in-use electronic component or package base has the impedance device therein, the cover can be connected to the constant potential portion when no signal is input to the electronic component. Consequently, alternation and deletion of the signal input to the electronic component can be prevented.

Furthermore, the constant potential portion may be a grounded portion. In this manner, the potential of the cover can be fixed at a ground potential.

Furthermore, the package base may have a piezoelectric resonator element therein, and the electronic component may include a processing and memory unit into which the signal is input and data is written and an oscillation unit oscillating the piezoelectric resonator element to output an oscillation signal and adjusting a frequency of the oscillation signal based on the data written into the processing and memory unit. In this manner, when the oscillation signal is output from the electronic device, the potential of the cover can be held constant. This can prevent a change in the oscillation frequency due to the influence of stray capacitance. In other words, the electronic device can output an oscillation signal having a constant frequency and it can thereby provide improved precision and reliability in operation.

An electronic device according to another aspect of the invention includes an electronic component, a package base having the electronic component therein and a conductive cover bonded to the package base, wherein the electronic component includes a processing and memory unit into which data input from outside is written, wherein a signal transmission line is provided to electrically connect the cover to the processing and memory unit so as to use the cover as a terminal for inputting a signal to the electronic component from outside, and wherein a switching circuit is arranged at a part of the signal transmission line to electrically connect the cover to the processing and memory unit when the data input from outside is written into the processing and memory unit and to electrically connect the cover to a constant potential portion in a normal use of the electronic device.

In this manner, in the normal use situation when the electronic device outputs a frequency signal (that is, when no data is written), the cover is connected to the constant potential portion by the switching circuit. Accordingly, even when a signal is input to the cover, it can be prevented that the signal is mistakenly written into the processing and memory unit. In addition, it can also prevent the alteration and deletion of data already written in the processing and memory unit. Moreover, when used for data input, the signal is input to the switching circuit via the cover and thereby can be input to the processing and memory unit. Additionally, since the cover serves as the terminal to which the signal is input, a probe supplying a signal can easily be contacted with the cover, thereby ensuring signal input precisely.

Furthermore, the switching circuit may be formed by using a transistor electrically connecting the cover to the constant potential portion at a voltage level lower than a predetermined voltage level and electrically connecting the cover to the processing and memory unit at a voltage level equal to or higher than the predetermined voltage level. When inputting a signal to the electronic device, using a signal having a voltage equal to or higher than a predetermined voltage allows the cover to be connected to the processing and memory unit. In this way, a signal can be input and written into the processing and memory unit.

Furthermore, the processing and memory unit may be integrally formed with the switching circuit. In this manner, it is unnecessary to mount the switching circuit as a discrete component in the package base. Accordingly, there is no need for an area to mount only the switching circuit, whereby space saving can be achieved.

Furthermore, the constant potential portion may be a grounded portion. In this manner, the potential of the cover can be fixed at a ground potential.

Furthermore, the package base may have a piezoelectric resonator element therein, and the electronic component may further include an oscillation unit oscillating the piezoelectric resonator element to output an oscillation signal and adjusting a frequency of the oscillation signal based on the data written into the processing and memory unit. When using a piezoelectric oscillator as the electronic device, in a normal use of the piezoelectric oscillator, the cover is connected to the grounded portion, whereby the potential of the cover can be kept at a ground potential. Consequently, regardless of the oscillator use situations on a user side, it can be prevented that the oscillation frequency of the piezoelectric oscillator changes due to the influence of stray capacitance occurring between an electrode pattern of the piezoelectric resonator element and the cover.

### BRIEF DESCRIPTION OF THE DRAWINGS

The invention will be described with reference to the accompanying drawings, wherein like numbers reference like elements.

FIG. 1 is a schematic circuit diagram of a piezoelectric oscillator according to a first embodiment of the invention.

FIG. 2A is a sectional view of the above piezoelectric oscillator.

FIG. 2B is a back surface view of the above piezoelectric oscillator.

FIG. 3 is a table illustrating functions allocated to external terminals and a cover.

FIG. 4 is an illustrative view showing probes coming in contact with the piezoelectric oscillator.

FIG. 5 is a schematic circuit diagram showing a modified example of an impedance element.

FIG. 6 is a schematic circuit diagram showing a modified example of a part connected to an impedance element.

FIG. 7 is a schematic plan view of a piezoelectric oscillator according to a second embodiment of the invention.

FIG. 8 is a schematic circuit view of a piezoelectric oscillator according to a third embodiment of the invention.

FIG. 9 is an illustrative view of a switching circuit.

FIG. 10 is a graph showing a relationship between a voltage V₁, supplied to the cover and a voltage V₂ input to a processing and memory unit.

### DESCRIPTION OF EXEMPLARY EMBODIMENTS

Embodiments of the invention will be described hereinafter. In the following embodiments, a piezoelectric oscillator is employed as an electronic device. However, the invention is not limited to those embodiments. For example, the invention may be applied to an embodiment in which a signal is input to an electronic component after the formation of the electronic device.

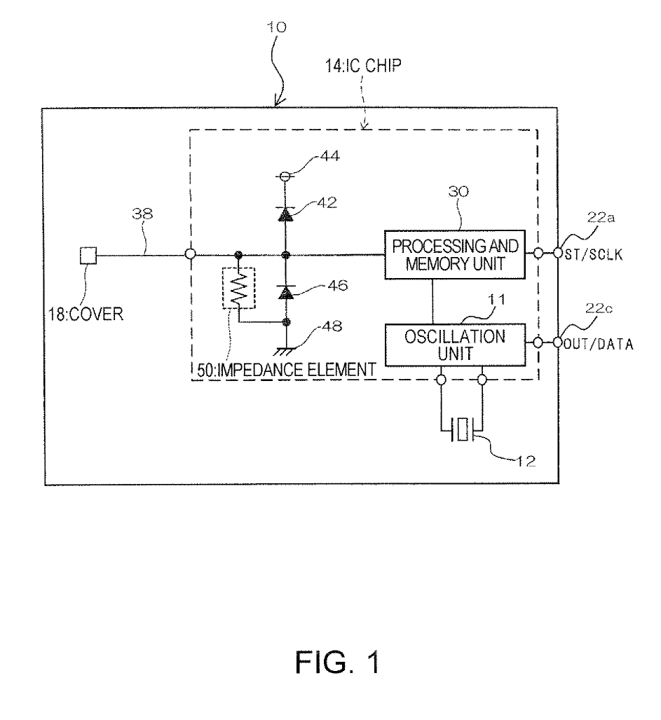

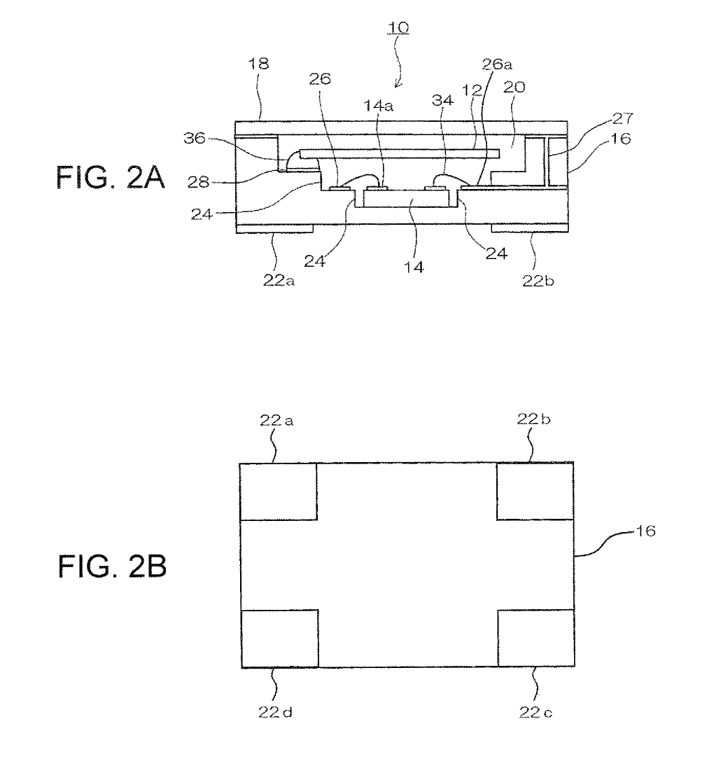

FIG. 1 is a schematic circuit diagram of a piezoelectric oscillator according to a first embodiment of the invention. FIG. 2A is a sectional view of the piezoelectric oscillator according to the first embodiment and FIG. 2B is a back surface view thereof. A piezoelectric oscillator 10 shown in FIG. 2A has a piezoelectric resonator element 12, an IC chip 14 (electronic component), a package base 16 and a cover 18. The piezoelectric oscillator 10 has the package base 16 in which an upwardly opening recessed portion 20 is formed. As shown in FIG. 2B, four external terminals 22a, 22b, 22c and 22d are disposed on a back surface of the package base 16. The recessed portion 20 disposed in the package base 16 has stair-like step portions 24 formed on side surfaces thereof The step portions 24 have a plurality of bonding electrodes 26 and a plurality of mount electrodes 28 disposed on upper surfaces thereof. FIG. 2A shows only one of the mount electrodes 28. A bonding electrode 26a, which is one of the bonding electrodes 26, is electrically connected to the cover 18 via a wiring pattern 27. Additionally, some of the other bonding electrodes 26 are electrically connected to the mount electrodes 28, whereas the rest thereof is electrically connected to the external terminals 22a to 22d.

The recessed portion 20 has the IC chip 14 on a bottom surface thereof. The IC chip 14 includes a processing and memory unit 30 having a memory unit, a writing control circuit, a terminal periphery circuit and the like, an oscillation unit 11 which oscillates the piezoelectric resonator element 12, etc. A wire bonding is provided on a pad 14a disposed on an upper surface of the IC chip 14, whereby the IC chip 14 is electrically connected to the bonding electrodes 26 disposed in the package base 16 via a wire 34. In addition, the piezoelectric resonator element 12 is disposed above the mount electrode 28 by using a conductive bonding material 36. The piezoelectric resonator element 12 is constituted by forming an electrode pattern (not shown in the figure) on a piezoelectric substrate. A metallic cover 18 airtightly sealing the recessed portion 20 is bonded onto an upper surface of the package base 16. The cover 18 is electrically connected to the IC chip 14 and therefore serves as a terminal for inputting a signal to the IC chip 14.

Next, a description will be given of an internal structure of the IC chip 14. In the piezoelectric oscillator 10, as shown in FIG. 1, the cover 18 (terminal) is electrically connected to the IC chip 14 via a signal transmission line 38. The signal transmission line 38 is drawn through the inside of the IC chip to be connected to the processing and memory unit 30. A power supply voltage portion 44 is connected to the signal transmission line 38 via a first rectifying element 42. The power supply voltage portion 44 has a constant potential and thus is a constant potential portion. The signal transmission line 38 is also connected to a grounded portion 48 via a second rectifying element 46. The grounded portion 48 is grounded and thus has a constant potential. Therefore, the grounded portion 48 is a constant potential portion. Furthermore, the signal transmission line 38 is connected to the grounded portion 48 via an impedance element 50. Specifically, the impedance element 50 is connected in parallel with the second rectifying element 46, where one end of the impedance element 50 is connected to the signal transmission line 38 and the other end thereof is connected to the grounded portion 48 The impedance element 50 may be, for example, a resistance element.

The processing and memory unit 30 is electrically connected to the external terminal 22a. Accordingly, a signal can be input from an outside of the piezoelectric oscillator 10 to the processing and memory unit 30.

The oscillation unit 11 formed in the IC chip 14 has an oscillation circuit oscillating the piezoelectric resonator 12 and outputs an oscillation signal from the oscillation circuit to the external terminal 22c.

The external terminals 22a to 22d and the cover 18 have the following functions. The functions of the external terminals 22a to 22d are different between a situation when a user normally use the oscillator (normal use situation),where the piezoelectric oscillator 10 outputs an oscillation signal from the external terminal 22c and a situation when data is written into the processing and memory unit 30. In other words, the external terminals 22a to 22d have functions in both situations of the normal use and the data input.

In the normal use situation when the piezoelectric oscillator 10 normally performs as an oscillator, the external terminals 22a to 22d may serve, for example, as a terminal (ST) for controlling whether or not the piezoelectric oscillator 10 may output a frequency signal, a grounded terminal (GND), a terminal (OUT) for outputting a frequency signal from the piezoelectric oscillator 10 and a terminal (Vcc) for supplying a power supply voltage. On the other hand, in the data writing situation, the external terminals 22a to 22d and the cover 18 may serve, for example, as an input terminal (SCLK) for inputting a serial clock signal used when inputting data, a terminal (DATA) for inputting data synchronized with the clock signal, the grounded terminal (GND), the terminal (Vcc) for supplying the power supply voltage and a terminal (PE) for inputting a signal for switching between the data-writing situation and the normal use situation.

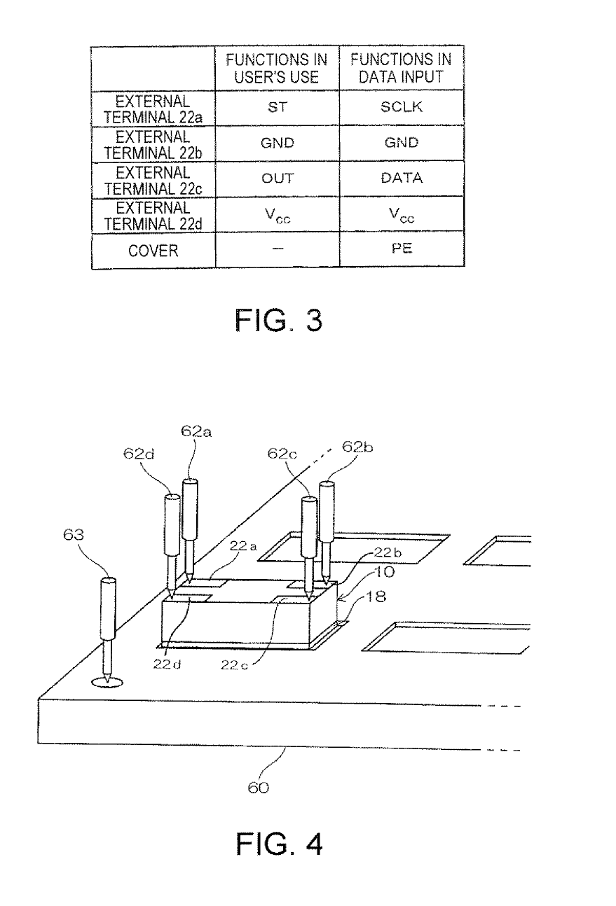

Consequently, the functions can be allocated to the external terminals 22a to 22d and the cover 18, as shown in FIG. 3. Here, the cover 18 may function as DATA or SCLK, instead of the PE function as shown in FIG. 3.

Next, a description will be given of an example regarding data writing into the piezoelectric oscillator 10. Data written into the memory of the processing and memory unit 30 of the IC chip 14 disposed in the piezoelectric oscillator 10 can be used as data for adjusting a frequency of the oscillation signal output from the piezoelectric oscillator 10. For example, when the piezoelectric oscillator 10 is a programmable piezoelectric oscillator having a phase synchronizing circuit, it is only necessary to use data for setting an arbitrary output frequency. In this case, based on data written in the memory unit of the processing and memory unit 30, the oscillation unit 11 outputs an oscillation signal of the arbitrary frequency. Alternatively, when the piezoelectric oscillator 10 is a temperature compensated piezoelectric oscillator having a temperature compensating function, it is only necessary to use data for compensating frequency-temperature characteristics of an oscillation signal according to temperatures. In this case, the oscillation unit 11 compensates the frequency-temperature characteristics of the oscillation signal based on data written in the memory of the processing and memory unit 30 and temperature information obtained by a temperature sensor disposed in the oscillation unit 11.

Then, in order to write data in the oscillator 10, for example, a manner as shown in FIG. 4 may be applied. FIG. 4 is an illustrative view of probes coming in contact with the piezoelectric oscillator 10. When data is written in, a tray 60 having a conductive surface is used. The piezoelectric oscillator 10 is placed on the tray 60 such that the tray 60 is in contact with the cover 18. Then, probes 62a to 62d are contacted with the external terminals 22a to 22d from an upper side of the piezoelectric oscillator 10, as well as the probe 63 is contacted with the tray 60. Here, the cover 18 is electrically connected to the probe 63. After this, disposing a plurality of the piezoelectric oscillator 10 on the tray 60 allows data to be written simultaneously into the plurality of piezoelectric oscillators 10.

Next, when the external terminals 22a to 22d and the cover 18 are allocated for the functions as shown in FIG. 3, the probes 62a to 62d and 63, which are contacted with the tray 60, supply a data writing signal to the cover 18 via the tray 60. In this situation, a signal of a predetermined voltage level is input to the probe 63 electrically connected to the cover 18 and then input to the IC chip 14 (processing and memory unit 30) via the signal transmission line 38. Then, the processing and memory unit 30 switches the functions of the external terminals 22a to 22d to SCLK, DATA, Vcc and GND. After this, the probe 62c electrically connected to the external terminal 22c as the data input terminal inputs data synchronized with a clock signal to the IC chip 14. The data is written into the processing and memory unit 30 disposed in the IC chip 14. Upon the completion of data writing therein to the probes 62a to 62d are separated from the external terminals 22a to 22d and the cover 18, which in turn return to normal use functions. In the normal use situation, the cover 18 is grounded via the impedance element 50.

Next, the piezoelectric oscillator 10 oscillates the piezoelectric resonator element 12 based on the data written into the processing and memory unit 30 and then outputs a frequency signal based on the oscillation frequency.

In the above piezoelectric oscillator 10, the impedance element 50 is arranged in a circuitry of the IC chip 14 to connect the signal transmission line 38 to the grounded portion 48. Accordingly, the cover 18 can have a constant potential. In addition, when mounting the piezoelectric oscillator 10 on a substrate of an electronic apparatus, the cover 18 of the piezoelectric oscillator 10 is grounded via the impedance element 50. Thus, regardless of the use situations on the user side of the oscillator, it can be prevented that the oscillation frequency fluctuates due to the influence of stray capacitance. In other words, even if the cover 18 of the piezoelectric oscillator 10 contacts with a metallic container for preventing a radio wave interference problem, the oscillation frequency of the piezoelectric oscillator 10 does not change because the cover 18 and the metallic container have the same ground potential.

The cover 18 is grounded via the impedance element 50, whereby electrostatic buildup can be prevented. In addition, in the piezoelectric oscillator 10, the impedance element 50 is disposed in the circuitry in the IC chip 14. Thus, there is no need for an area to externally mount the impedance element 50. Therefore, space saving can be achieved.

The external terminals 22a to 22d of the piezoelectric oscillator 10 have functions used in the normal use situation and the processing-data writing situation. Accordingly, those terminals can have respective functions in both of the situations. Consequently, in the piezoelectric oscillator 10, it is unnecessary to discretely dispose a terminal for functioning in the normal use and a terminal for functioning in the data input. This can reduce the number of terminals contacted with probes. Additionally, even when mounting the piezoelectric oscillator 10 and other electronic devices on a substrate with high density, the possibility can be significantly reduced that the terminals will contact with the other electronic devices, due to the small number of terminals coming in contact with the probes. Furthermore, even if any of the terminals happens to contact with the electronic devices and thereby an electric signal is added, alternation and deletion of data written in the IC chip 14 (processing and memory unit 30) can be prevented because of the grounded terminal 22b.

In the piezoelectric oscillator 10, the probes 62a to 62d come in contact from the upper direction thereof Thus, it is easy to check whether or not the probes 62a to 62d are in contact with the external terminals 22a to 22d. Particularly, in the case as shown in FIG. 4, it is only necessary to contact the probes 62a to 62d and 63 with the external terminals 22a to 22d and the tray 60 from only one direction. Therefore, they can very easily be contacted with the probes. Consequently, a signal from outside can reliably be input to the processing and memory unit 30 in the piezoelectric oscillator 10, as well as data from outside can be written therein without fail.

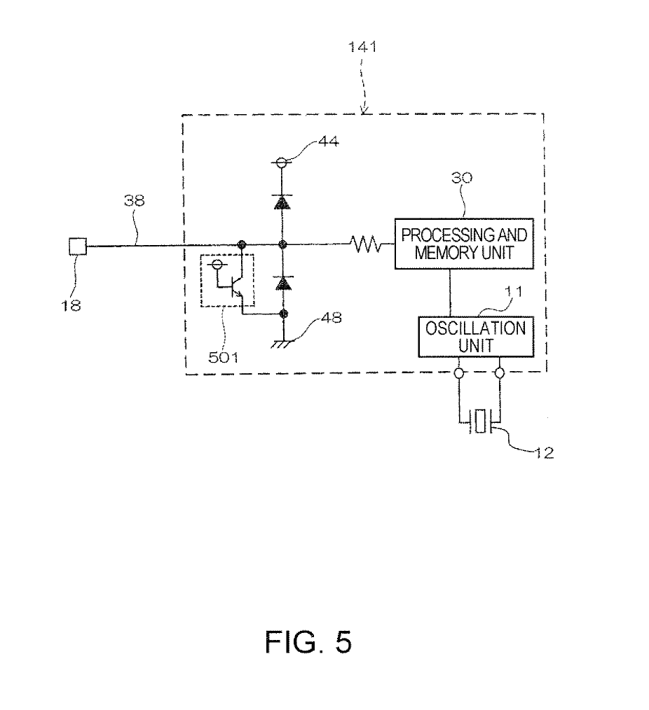

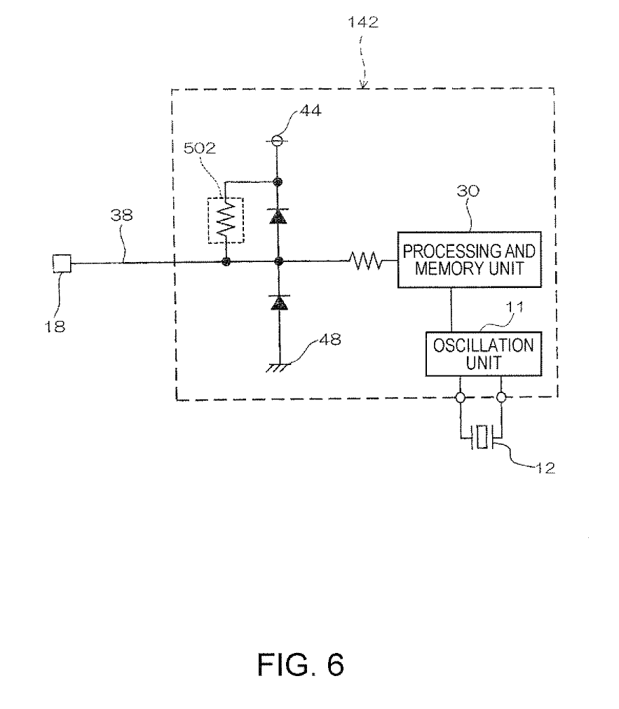

In the above-described embodiment, it has been described that as the impedance element, for example, a resistance element may be used. Alternatively as shown in FIG. 5, a transistor 501 may be used as the impedance element. Additionally, the constant potential portion connected to the cover 18 via the impedance element is not limited to the grounded portion 48. In accordance with embodiments of the invention, as shown in FIG. 6, for example, the cover 18 may be connected to the power-supply voltage portion 44 via an impedance element 502.

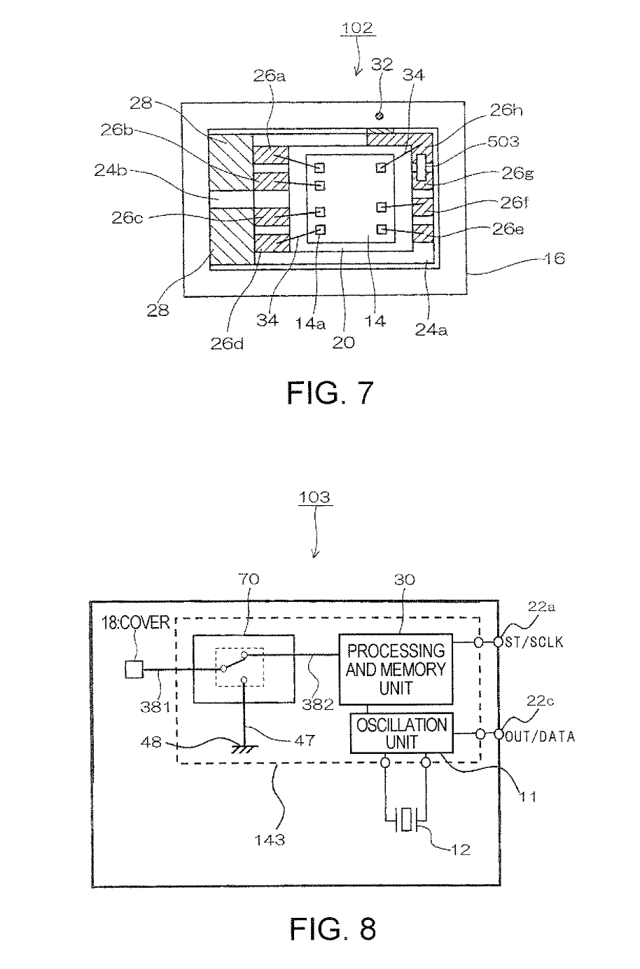

Next, a second embodiment of the invention will be described. In this embodiment, the same structural parts as those in the first embodiment will have the same reference numerals, and descriptions thereof will be omitted or briefed. FIG. 7 is a schematic plan view of a piezoelectric oscillator according to the second embodiment. In FIG. 7, descriptions of the cover and the piezoelectric resonator element will be omitted.

A piezoelectric oscillator 102 according to the second embodiment includes the piezoelectric resonator element 12, the IC chip 14, the package base 16 and the cover 18. The package base 16 included in the piezoelectric oscillator 102 of the second embodiment has the external terminals 22a to 22d formed on the back surface thereof. as in the piezoelectric oscillator 10 of the first embodiment shown in FIG. 2. The package base 16 has the recessed portion 20 with stair-like steps formed on the side surfaces thereof. The plurality of bonding electrodes 26 (26a to 26h) is disposed on a lower step 24a formed in the recessed portion 20, whereas the mount electrode 28 is disposed on an upper step 24b. The one bonding electrode 26h is electrically connected to a through-hole 32 formed on a sidewall of the package base 16. The through-hole 32 is extended out on the upper surface of the package base 16 to be electrically connected to the metallic cover 18 bonded onto the upper surface of the package base 16. In addition, the bonding electrode 26g, which is adjacent to the bonding electrode 26h electrically connected to the cover 18, is formed on a back surface of the package base 16 to be electrically connected to the grounded external terminal 22b. Any of the other bonding electrodes 26a to 26f is electrically connected to the mount electrode 28, whereas the rest thereof is electrically connected to the external terminals 22a, 22c and 22d, except for the grounded external terminal 22b.

In the above package base 16, the impedance element 503 is mounted above the bonding electrode 26h electrically connected to the cover 18 and the bonding electrode 26g electrically connected to the grounded external terminal 22b. Thus, the bonding electrodes 26g and 26h are electrically connected to each other via the impedance element 503. The recessed portion 20 has the IC chip 14 on the bottom surface thereof. A wire bonding is provided on the pad 14a disposed on the IC chip 14 and the bonding electrodes 26a to 26f and 26h to electrically connect them via the wire 34. The IC chip 14 employed in the second embodiment is similar to that shown in FIG. 1, but does not include an impedance element.

Additionally, the piezoelectric resonator element 12 is mounted above the mount electrode 28 in the same manner as shown in FIG. 2A. Also, the cover 18 is bonded onto the package base 16 to airtightly seal the recessed portion 20 in the same manner as shown in FIG. 2A. In the above piezoelectric oscillator 102, data writing can be performed in the same manner as that of the first embodiment.

Furthermore, the package base 16 of the piezoelectric oscillator 102 has the impedance element 50 therein. Thus, the cover 18 can have a constant potential. When mounting the piezoelectric oscillator 102 on a substrate of an electronic apparatus, regardless of the use situations on the user side, oscillation-frequency fluctuations due to the influence of stray capacitance can be prevented, because the cover 18 of the piezoelectric oscillator 102 is grounded via the impedance element 503.

Since the cover 18 is also grounded via the impedance element 50, an electrostatic buildup can be prevented. In addition, the impedance element 50 can be mounted in the package base 16. Thus, even when the IC chip 14 does not have the impedance element 50 for connecting the signal transmission line 38 to the constant potential portion, the cover 18 can be set at a constant potential via the impedance element 50.

Furthermore, the external terminals 22a to 22d of the piezoelectric oscillator 102 have functions in the normal use situation and the processing-data writing situation. Accordingly, those terminals can function in both of the situations. Thus, it is possible to reduce the number of terminals for functioning in the normal use and the data-writing situations. Moreover, even when mounting the piezoelectric oscillator 102 and other electronic devices on a substrate with high density, the possibility can be significantly reduced that the terminals will contact with the other electronic devices, because of the small number of terminals contacting with the probes 62. Also, even if the terminals contact with any of the electronic devices and an electric signal is thereby loaded, alternation and deletion of data written into the IC chip 14 (processing and memory unit 30) can be prevented because of the grounded terminal 22b.

In the piezoelectric oscillator 102, the probes 62a to 62d and 63 come in contact from the upper direction thereof Thus, it is easy to check whether or not the probes 62a to 62d and 63 are in contact with those terminals or the like. Consequently, a signal from outside can be reliably input to the processing and memory unit 30 in the piezoelectric oscillator 102, as well as the data from outside can be written therein without fail.

Next, a third embodiment of the invention will be described. In this embodiment, the same structural parts as those in the first embodiment will have the same numerals, and descriptions thereof will be omitted or briefed.

A sectional view of a piezoelectric oscillator 103 according to the third embodiment is the same as that of the piezoelectric oscillator 10 according to the first embodiment as shown in FIG. 2A. FIG. 8 is a schematic circuit diagram of the piezoelectric oscillator 103 according to the third embodiment. As shown in FIG. 8, the cover 18 is connected to an IC chip 143. The IC chip 143 includes the processing and memory unit 30 having a memory, a writing control circuit, a terminal peripheral circuit, etc, a switching circuit 70, the oscillation unit 11 oscillating the piezoelectric resonator element 12, etc. The processing and memory unit 30 is connected to the cover 18 via a signal transmission line 382, the switching circuit 70 and then a signal transmission line 381. The switching circuit 70 is disposed between the signal transmission lines 381 and 382. Additionally, the switching circuit 70 is connected to the grounded portion 48 via a ground line 47. A portion connected to the cover 18 via the switching circuit 70 is not limited to the grounded portion 48. In accordance with embodiments of the invention, for example, the cover 18 may be connected to a power-supply voltage portion as a constant potential portion.

The switching circuit 70 connects the cover 18 to the processing and memory unit 30 of the piezoelectric oscillator 103 so that the cover 18 can input a signal to the processing and memory unit 30 when data is written into the processing and memory unit 30 thereof. Additionally, the switching circuit 70 connects the cover 18 to the grounded portion 48 in a normal use situation when the piezoelectric oscillator 103 outputs an oscillation signal. In the third embodiment, when a voltage level of a signal input to the cover 18 is lower than a predetermined voltage level Vth, the switching circuit 70 connects the cover 18 to the grounded portion 48, whereas it connects the cover 18 to the processing and memory unit 30 when the voltage level of the input signal is equal to or higher than the predetermined voltage Vth.

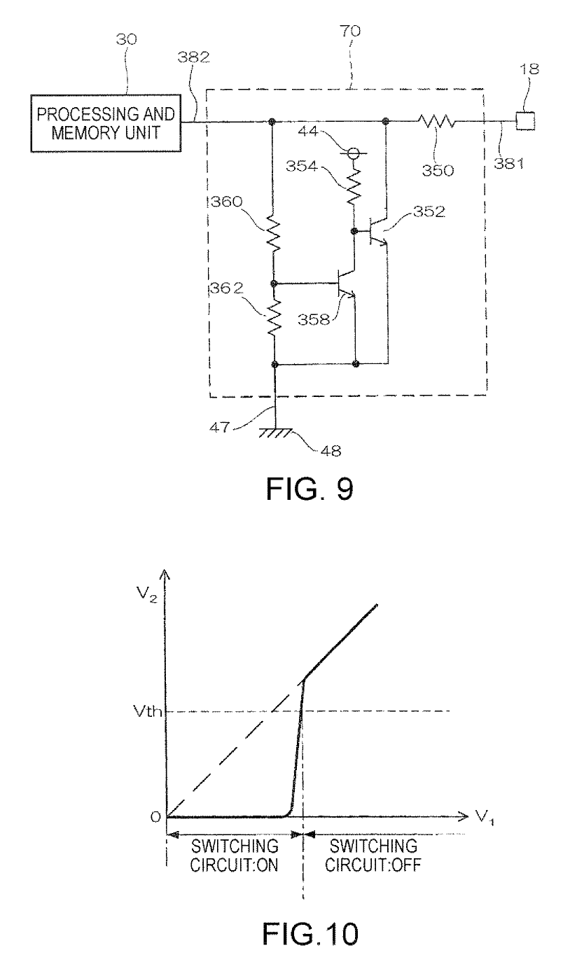

Next, a detailed explanation will be given of the switching circuit 70. FIG. 9 is an illustrative view of the switching circuit 70. In this circuit, a first resistance element 350 is disposed between the signal transmission lines 381 and 382 connecting the cover 18 to the processing and memory unit 30. A latter part of the first resistance element 350 is forked into two branches, one of which is connected to the processing and memory unit 30 and the other is connected to a collector of a first transistor 352. An emitter of the first transistor 352 is connected to the grounded portion 48 and a base thereof is connected to the power supply voltage portion 44 via a second resistance element 354. in addition, the base of the first transistor 352 is connected to a collector of a second transistor 358. An emitter of the second transistor 358 is connected to the grounded portion 48. A base of the second transistor 358 is connected to the signal transmission line 38 via a third resistance element 360 and also connected to the grounded portion 48 via a fourth resistance element 362.

In the piezoelectric oscillator 103 of the third embodiment, as in the case of the piezoelectric oscillator 10 of the first embodiment, the functions shown in FIG. 3 are allotted to the external terminals 22a to 22d and the cover 18. Upon data writing, that is, when data is written into the processing and memory unit 30, a signal input from the cover 18 has a voltage level equal to or higher than a predetermined voltage level Vth of the switching circuit 70. Here, FIG. 10 shows a relationship between a voltage V₁ supplied to the cover 18 and a voltage V₂ input to the processing and memory unit 30. In a situation when no signal is input to the cover 18 of the piezoelectric oscillator 103, the switching circuit 70 is turned on, whereby the cover 18 is connected to the grounded portion 48.

Meanwhile, when data is written thereinto, a voltage equal to or higher than the predetermined voltage Vth is applied to the cover 18, whereby the switching circuit 70 is turned off and the cover 18 is thereby connected to the processing and memory unit 30. Then, the processing and memory unit 30 switches the functions of the external terminals 22a to 22d to SCLK, DATA, Vcc and GND. After this, data, which is synchronized with a clock signal input from the external terminal 22a, is input from the external terminal 22c to the IC chip 143 to be written into the processing and memory unit 30 in the IC chip 143. Upon completion of the data writing, the voltage applied to the cover 18 becomes 0V or a voltage lower than the Vth, whereby the switching circuit 70 is turned on and the cover 18 is thereby connected to the grounded portion 48. In other words, the external terminals 22a to 22d and the cover 18 perform the functions allotted for the normal use situation as shown in FIG. 3.

In the piezoelectric oscillator 103 described above, in the normal use situation (not in the data-writing use situation) in which the piezoelectric oscillator 103 oscillates a frequency signal, the switching circuit 70 connects the cover 18 to the grounded portion 48. Thus, it can prevent accidental writing into the processing and memory unit 30, as well as alteration and deletion of the data written into the processing and memory unit 30.

In addition, when inputting data to the piezoelectric oscillator 103, a signal having a voltage level equal to or higher than the predetermined voltage level Vth is input to the switching circuit 70. Accordingly, the switching circuit 70 is turned off so that the cover 18 can be connected to the processing and memory unit 30. In this manner, data can be input and written into the piezoelectric oscillator 103 from outside.

Furthermore, in the normal use of the piezoelectric oscillator 103, the cover 18 is connected to the grounded portion 48 and thereby the cover 18 has the ground potential. Accordingly, regardless of the use situations on the user side, it can be prevented that the oscillation frequency of the piezoelectric oscillator 103 fluctuates due to the influence of stray capacitance between the electrode pattern of the piezoelectric resonator element 12 and the cover 18. Specifically, even if the cover 18 of the piezoelectric oscillator 103 contacts with a metallic shield container or the like for preventing a radio wave interference problem, the oscillation frequency of the piezoelectric oscillator 103 does not change because the cover 18 and the container have the same ground potential. Moreover, the cover 18 is grounded via the switching circuit 70, which can prevent an electrostatic buildup in the cover 18.

Furthermore, in the piezoelectric oscillator 103, the switching circuit 70 is disposed in the IC chip 14. Thus, there is no need for an area to externally mount the switching circuit 70, thereby achieving space saving.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The entire disclosure of Japanese Patent Application Nos: 2005-348050, filed Dec. 1, 2005 and 2005-348051 filed Dec. 1, 2005 are expressly incorporated by reference herein.

1. An electronic device, comprising:
an electronic component;
a package base having the electronic component therein; and
a conductive cover bonded to the package base;
wherein a signal transmission line is provided to electrically connect the cover to the electronic component so as to use the cover as a terminal for inputting a signal to the electronic component from outside; and
wherein the signal transmission line is connected to a constant potential portion via an impedance element.

2. The electronic device according to claim 1, wherein the impedance element is integrally formed with the electronic component.

3. The electronic device according to claim 1, wherein the package base has the impedance element therein.

4. The electronic device according to claim 1, wherein the constant potential portion is a grounded portion.

5. The electronic device according to claim 1, wherein the package base has a piezoelectric resonator element therein; and wherein the electronic component includes a processing and memory unit into which the signal is input and data is written and an oscillation unit oscillating the piezoelectric resonator element to output an oscillation signal and adjusting a frequency of the oscillation signal based on the data written into the processing and memory unit.

6. An electronic device, comprising:
an electronic component;
a package base having the electronic component therein; and
a conductive cover bonded to the package base;
wherein the electronic component includes a processing and memory unit into which data input from outside is written;
wherein a signal transmission line is provided to electrically connect the cover to the processing and memory unit of the electronic component so as to use the cover as a terminal for inputting a signal to the electronic component from outside; and
wherein a switching circuit is arranged at a part of the signal transmission line to electrically connect the cover to the processing and memory unit when the data input from outside is written into the processing and memory unit and to electrically connect the cover to a constant potential portion in a normal use of the electronic device.

7. The electronic device according to claim 6, wherein the switching circuit is formed by using a transistor electrically connecting the cover to the constant potential portion at a voltage level lower than a predetermined voltage level and electrically connecting the cover to the processing and memory unit at a voltage level equal to or higher than the predetermined voltage level.

8. The electronic device according to claim 6, wherein the processing and memory unit is integrally formed with the switching circuit.

9. The electronic device according to claim 6, wherein the constant potential portion is a grounded portion.

10. The electronic device according to claim 6, wherein the package base has a piezoelectric resonator element therein; and wherein the electronic component further includes an oscillation unit oscillating the piezoelectric resonator element to output an oscillation signal and adjusting a frequency of the oscillation signal based on the data written into the processing and memory unit.
